(19) United States
(12) Patent Application Publication
(10) Pub. No.: US 2012/0211740 A1
(43) Pub. Date: Aug. 23, 2012

(54) Method for Fabricating Organic Devices

(75) Inventor: Robert Müller, Leuven (BE)

(73) Assignees: Nederlandse Organisatie Voor Toegepast- Natuurwetenschappelijk Onderzoek Tno, Delft (NL); IMEC, Leuven (BE)

(21) Appl. No.: 13/503,658

(22) PCT Filed: Oct. 25, 2010
(86) PCT No.: PCT/EP2010/066082

§ 371 Date: Apr. 24, 2012

Related U.S. Application Data
(60) Provisional application No. 61/254,848, filed on Oct. 26, 2009.

(51) Int. Cl. H01L 51/30; H01L 51/48; H01L 51/56; H01L 51/40

(52) U.S. Cl. 257/40; 438/99; 257/E51.025; 257/E51.026

(57) ABSTRACT

The present invention relates to a method for fabricating an organic device, said method comprising: (i) Providing a substrate (1) having a surface comprising electrical contact structures (4) and a dielectric portion (3), (ii) Providing a first temporary protection layer (9) on some or all of said electrical contact structures (4), (iii) Providing a first surface modification layer (6) on the dielectric portion (3) and/or providing a third surface modification layer (10) on said electrical contact structures (4) not protected in step (ii), (iv) Removing the first temporary protection layer (9), (v) Providing a second surface modification layer (5) on the electrical contact structures that where protected in step (ii), and (vi) Providing said first surface modification layer (6) on the dielectric portion (3), if it was not provided in step (iii), and (vii) Providing an organic semiconductor layer (7) on top of at least part of said first surface modification layer (6) and on top of said second (5) surface modification layer and if present on top of said third surface modification layer (10), thereby obtaining said organic device or providing an organic semiconductor layer of a first type (7) on top of said second surface modification layer (5) and part of said first surface modification layer (6) and providing an organic semiconductor layer of a second type (8) on top of said third surface modification layer and another part of said first surface modification layer (6), thereby obtaining said organic device.

### TECHNICAL FIELD OF THE INVENTION

The present invention relates to methods for fabricating organic devices, more in particular organic transistors, and to organic devices, e.g. organic transistors thus obtained.

### BACKGROUND OF THE INVENTION

The performance of organic bottom contact transistors (wherein a semiconductor layer is provided on top of the source/drain contacts and the dielectric layer), such as e.g. pentacene transistors comprising gold bottom contacts and a SiOx (or AlOx) dielectric layer, can be improved by providing a silane or a phosphonic acid layer on the dielectric layer, and by providing a self-assembled monolayer (SAM, typically thiols) on the gold contacts before depositing the pentacene layer. As reported by S. A. DiBenedetto et al. in “Molecular Self-Assembled Monolayers and Multilayers for Organic and Unconventional Inorganic Thin-Film Transistor Applications”, Advanced Materials, 2009, 21, 1407-1433, this approach leads to a reduction of contact resistances by enhancing the semiconductor adhesion and growth orientation relative to the metal source/drain electrodes. Surface modification leads to optimal wetting of the substrate, leading to favorable large-grained first (pentacene) layer growth and thus a good morphology and good charge mobility within the pentacene layer, resulting in an enhanced performance of bottom contact thin film transistors.

In prior art processes, as e.g. described in EP 2091077, after providing the dielectric layer and the bottom contacts, a cleaning step, e.g. using UV ozone cleaning is performed. Then the surface treatment of the (gold) bottom contacts with thiols is performed, and afterwards e.g. silanes are provided on the dielectric layer. Therefore, during the surface treatment with silane, the thiols are already present on the gold surface. The reason for this sequence of steps is to avoid bonding of silanes to the gold bottom contacts that may be (partly) oxidized e.g. as a result of a UV-ozone cleaning step performed after forming the (gold) bottom contacts. Oxidation of the gold during UV ozone cleaning may lead to an unstable gold oxide (as e.g. described by Tsai et al, Surface Science 537 (2003), L447-L450). Therefore, when reversing the sequence of surface treatment steps (i.e. first performing a silane treatment and afterwards performing a thiol treatment), the silanes may bond to the (unstable) gold oxide, and thus the silane layer on the gold (oxide) would also be unstable. However, silane deposition is typically done from the gas phase in low vacuum and at temperatures around 100° C. At these temperatures, thiols (and other SAMs) can partly desorb. Silanization could also be performed from a solution of the silane in a solvent. However, experiments indicate that gas phase silanization leads to better results than solution phase silanization. In case of solution phase silanization not only a monolayer, but sometimes also additional silane may be present on the substrate, leading to a less uniform surface.

In US 2004/161,873 a process is described wherein the silane is provided before providing the thiols. In this process the gold bottom contacts are provided after UV-ozone cleaning of the silicon dioxide. This may prevent oxidation of the gold. However, depositing gold after the cleaning requires the use of shadow mask techniques (to avoid the need for an UV-ozone cleaning step after gold deposition). Using shadow mask techniques for forming the metal contacts may lead to a non-uniform thickness of the metal contacts (i.e. with ‘spikes’ at the edges). When using shadow mask techniques the obtainable channel length is relatively large (typically several tens of micrometers) and thus the frequency of the corresponding circuits is limited. Smaller channel lengths could for example be obtained by means of lift-off techniques. However, lift-off techniques require photoresists, developers, solvents, . . . such that an UV-ozone cleaning step needs to be performed after metal contact formation to remove all contaminants.

### SUMMARY OF THE INVENTION

It is an object of the present invention to provide good methods for fabricating organic devices.
In a first aspect, the present invention relates to a method for fabricating an organic device. In particular, said method may comprise:
(i) Providing a substrate (1) having a surface comprising electrical contact structures (4) and a dielectric portion (3),
(ii) Providing a first temporary protection layer (9) on some or all of said electrical contact structures (4),
(iii) Providing a first surface modification layer (6) on the dielectric portion (3) and/or providing a third surface modification layer (10) on said electrical contact structures (4) not protected in step (ii),
(iv) Removing the first temporary protection layer (9),
(v) Providing a second surface modification layer (5) on the electrical contact structures that where protected in step (ii), and
(vi) Providing said first surface modification layer (6) on the dielectric portion (3), if it was not provided in step (iii),
(vii) Providing an organic semiconductor layer (7) on top of at least part of said first surface modification layer (6) and on top of said second (5) surface modification layer and if present on top of said third surface modification layer (10), thereby obtaining said organic device or providing an organic semiconductor layer of a first type (7) on top of said second surface modification layer (5) and part of said first surface modification layer (6) and providing an organic semiconductor layer of a second type (8) on top of said third surface modification layer and another part of said first surface modification layer (6), thereby obtaining said organic device.
In an embodiment of the first aspect, step (i) may comprise:
Providing a substrate (1),
Providing a dielectric layer (3) on said substrate (1), and
Providing electrical contact structures (4) on said dielectric layer (3),
thereby forming a substrate (1) having a surface comprising electrical contact structures (4) and a dielectric portion (3).
In an embodiment of the first aspect, in step (ii), a first temporary protection layer (9) may be provided on all the electrical contact structures (4), wherein step (iii) may consist in providing a first surface modification layer (6) on the dielectric portion (3), wherein step (vi) is not performed and wherein step (vii) may consist in providing an organic semiconductor layer (7) on top of said first (6) and said second (5) surface modification layer, thereby obtaining said organic device.
Alternatively, in step (ii), a first temporary protection layer (9) may be provided on only some of said electrical contact structures (4), wherein in step (iii) a first surface modification layer (6) may be provided on the dielectric portion (3) and a third surface modification layer (10) may be provided on the electrical contact structures (4) not protected in step (ii), wherein step (vi) is not performed, and wherein in step (vii) an organic semiconductor layer (7) may be provided on top of said first (6), second (5) and third (10) surface modification layer, thereby obtaining said organic device.
As yet another alternative, in step (ii), a first temporary protection layer (9) may be provided on only some of said electrical contact structures (4), wherein step (iii) may consist in providing a third surface modification layer (10) on said electrical contact structures (4) not protected in step (ii), wherein step (vi) may consist in providing said first surface modification layer (6) on the dielectric portion (3) and wherein in step (vii) an organic semiconductor layer (7) may be provided on top of said first (6), second (5) and third (10) surface modification layer, thereby obtaining said organic device.
As yet still another alternative, in step (ii), the first temporary protection layer (9, 11) may be provided on some of said electrical contact structures (4), a further step may be performed between step (ii) and step (iii) wherein a second temporary protection layer (12) is provided at least on the electrical contact structures (4) not provided with said first temporary protection layer (9, 11).
In yet another alternative, in step (ii), the first temporary protection layer (9) may be provided on all of said electrical contact structures (4) and a further step may be performed between step (ii) and step (iii) wherein a second temporary protection layer (12) is provided on some of said electrical contact structures (4) covered by said first temporary protection layer (9, 11).
In an embodiment of the first aspect, electrical structures (4) may be provided in step (i) via a first photolithographical metalization step and said first temporary protection layer (9) may provided in step (ii) via a second photolithographical metalization step.
In an embodiment, step (ii) may comprise masking, e.g. with a shadow mask, part of said electrical contact structures (4).
In an embodiment, step (ii) may comprise first providing a first temporary protection layer (9) on all of said electrical contact structures, followed by removing said first temporary protection layer (9) from some of said electrical contact structures, thereby providing a first temporary protection layer (9) on some of said electrical contact structures.
As an additional feature of the above embodiment, said step of removing said first temporary protection layer (9) from some of said electrical contact structures may comprise selectively contacting said first temporary protection layer (9) to be removed in step (ii) to an etchant solution.
In an embodiment of the first aspect, providing the first temporary protection layer may be performed using a lift-off process, e.g. during a preparation of the electrical contact structures (4).
For instance, the step of providing said electrical contact structures (4) and the step of providing said first temporary protection layer (9) may comprise the step of patterning said electrical contact structures (4) and said first temporary protection layer (9) in a single lift-off step before to provide said first surface modification layer (6).
Alternatively, the first temporary protection layer (9) may be provided after forming the electrical contact structures (4), e.g in a separate step using a different technique.
In an embodiment of the first aspect, the method may further comprise a step of performing a cleaning step after any one of step (i) to (vii). For instance, a cleaning step may be performed after the step of providing said first temporary protection layer (9) and before the step of removing said first temporary protection layer (9). As another example, a cleaning step can be performed after step (iii) and before step (iv). As yet another example, a cleaning step may be performed after step (iv) and before step (v) and/or after step (v) and before step (vi).
In an embodiment, said first temporary protection layer (9) may be provided by electrodeposition or electroless deposition.
In an embodiment, said first temporary protection layer (9) may comprise an organic or an inorganic material.
As an additional feature, said inorganic material may be or comprise a metal, a metal salt or a metal oxide.
As an additional feature, said metal may be selected from the list consisting of Al, Cu, Mg, Zn, Ti, Zr, Hf, mixtures and combinations thereof. Hence, in embodiments, said inorganic material may be selected from the list consisting of Al, Cu, Mg, Zn, Ti, Zr, Hf, salts thereof, oxides thereof, mixtures and combinations thereof.
When said first temporary protection layer comprises an organic material, said organic material may be or comprise a polymer.
As an additional feature, said polymer may be deposited on said electrical contact structures by electrochemical polymerization of its monomer.
As an additional feature, said monomer may be deposited from an aqueous solution.
In an embodiment, said first temporary protection layer (9) may be a stack of two or more layers.
In an embodiment, said first temporary protection layer (9) may be from 2 to 10 nm thick.
In an embodiment, the application of the first surface modification layer (6) may comprise reaction of the surface with a vapour or with a solution of a reagent.
In an embodiment, the application of the first surface modification layer (6) may comprise spin coating or spray coating.
In an embodiment, the step of removing the first temporary protection layer (9) may be performed by a chemical treatment that does not deteriorate the first surface modification layer (6).
In an embodiment, said first temporary protection layer may be organic and said first temporary protection layer may be removed via dissolution in an organic solvent.
Alternatively, In an embodiment wherein said first temporary protection layer comprises or is a metal, said metal may have a redox potential lower than the redox potential of the metal of the electrical contact structures (4) and said metal may be removed by an electrochemical process.
In an embodiment, said first surface modification layer (6) may comprise a silane, an organic phosphonic acid or a carboxylic acid.
As an additional feature, said silane may be selected from the group consisting of octadecyltrichlorosilane (OTS) and phenylethyltrichlorosilane (PETS).
In an embodiment, said first surface modification layer and said electrical contact structures may be respectively hydrophobic and hydrophilic relative to each other.
In an embodiment, said electrical contact structures (4) may comprise a bottom adhesion layer and a top layer directly adjacent to said bottom adhesion layer and further away from the substrate (1) than said bottom adhesion layer.
As an additional feature, said bottom adhesion layer may be from 2 to 30 nm thick and said top layer may be from 10 to 40 nm thick.
In an embodiment, said electrical contact structures (4) may have a thickness of from 12 to 70 nm, preferably form 20 to 50 nm.
In an embodiment, said electrical contact structures (4) may comprise or may be made of Au, Pt, Pd, Ag or Cu.
In an embodiment, said electrical contact structures (4) may comprise or may be made of Au, Pt or Pd.
For instance, said electrical contact structures (4) may comprise a gold or titanium bottom adhesion layer and a silver top layer.
As another example, said electrical contact structures (4) may comprise TiW as a bottom adhesion layer and Pd as a top layer directly adjacent to said bottom adhesion layer and further away from the substrate (1) than said bottom adhesion layer.
Yet as another example, said electrical contact structure may comprise gold as a top layer or may consist of gold and said first temporary protection layer may comprise Al.
In embodiments where said electrical contact structures comprise or are made of Au, Pt, Pd, Ag or Cu, said first temporary protection layer (9) may for instance comprise Al, Mg or Zn. As an example, it may comprise Al.
In embodiments where said electrical structures comprise or are made of Au, Pt or Pd, said first temporary protection layer (9) may be made of Cu.
In embodiments where said electrical structures comprise or are made of Au, Pt or Pd, a first and a second temporary protection layer may for instance be provided and said first temporary protection layer may be Cu and said second temporary protection layer may be Al.
In embodiments wherein said temporary protection layer comprise Al, Mg or Zn, said first temporary protection layer may for instance be removed by means of a diluted acid, e.g. hydrochloric or sulphuric acid.
As an additional feature, said diluted acid may comprise one volume of concentrated acid for from 2 to 10 volumes of water, preferably from 4 to 6 volumes of water.
In embodiments wherein said temporary protection layer comprise Al, said first temporary protection layer may be removed by a diluted base.
In embodiments wherein said temporary protection layer is made of Cu, the Cu protection layer may be removed by means of a diluted nitric acid.
For instance, said diluted acid may comprise one volume of concentrated nitric acid for 5-20 volume of water.
In embodiments, the contact time with said diluted acid or said diluted base may be from 1 to 60 min.
In an embodiment, said first surface modification layer (6) may be different from said second surface modification layer and/or said third surface modification layer.
As an additional feature, said difference may be in the chemical nature of said first and said second surface modification layer.
In an embodiment, said second and/or said third surface modification layer may comprise one of a thiol, an organic disulfide, a substituted thiourea, an isothiocyanate, a thiophene, an imidazole-2-thione, a selenol, an organic diselenide, a thioacetate, a nitrile or an isonitrile.
In an embodiment, said second and/or said third surface modification layer may comprise a charge-transfer complex.
For instance, said charge-transfer complex may be tetrathiafulvalene-tetracyanoquinodimethane.
In an embodiment, said second surface modification layer (5) and/or said third surface modification layer (10) may be self-assembled monolayers.
In an embodiment, said third surface modification layer (10) may be a self-assembled monolayer selected so that the bond strength with the electrical contact structure (4) is lower than the bond strength of the second surface modification layer (5) with the electrical contact structure (4).
For instance, said second surface modification layer (5) may be diphenyldisulfide and said third surface modification layer (10) may be pentafluorobenzenethiol.
In an embodiment where said second surface modification layer (5) and/or said third surface modification layer (10) are self-assembled monolayers, said third surface modification layer (10) may be a self-assembled monolayer and said second surface modification layer (5) may be provided so as to saturate the surface of the electrical contact structure on which it is provided.
In an embodiment where said second surface modification layer (5) and/or said third surface modification layer (10) are self-assembled monolayers, said second and/or said third surface modification layer (10) may be provided as a gas.
In an embodiment, said electrical contact structure (4) may be made of copper or silver or may have a copper or silver top layer and said second surface modification layer (5) may be provided by reacting said copper or silver with tetracyanoquinodimethane, sulphur or selenium.
In an embodiment, the method of the first aspect may comprise a step of performing a cleaning, preferably a solvent cleaning, after having provided said first (6), second (5) and optionally third (10) surface modification layers and prior the step of providing said organic semiconductor layer (7).
In an embodiment, said organic semiconductor layer may be pentacene or a pentacene derivative.
In an embodiment, said electrical contact structure (4) may be made of a metal and said method may further comprise the step of reacting the electrical contact structure with an electron acceptor or a chemical compound or mixture of compounds acting as a dopant for the semiconductor at the electrical contact structures (4)—semiconductor layer (7) interface or improving charge injection into the semiconductor at the electrical contact structures (4)—semiconductor layer (7) interface.
As an additional feature, said electrical contact structure may consist of silver or copper or may comprise silver or copper as a top layer and said electron acceptor may be sulphur or selenium.
Alternatively, said electrical contact structure may consist of copper or comprise copper as a top layer and said electron acceptor may be tetracyanoquinodimethane.
In an embodiment, said second surface modification layer may be provided by contacting said electrical contact structure with a liquid solution of a reactant.
As an additional feature, said liquid solution may have more affinity for the electrical contact structures than for the first surface modification layer (6) on the dielectric layer.
As an additional feature, said liquid solution may be provided via spin coating, dip coating or via inkjet.
For instance, said liquid solution may be provided via inkjet from two different nozzles of a print-head.
In an embodiment, said surface modification layer may be provided by evaporating a solvent of said liquid solution after its contacting with said electrical contact structure.
In an embodiment, said organic semiconductor layer of a first type (7) may be of a p-type or of a n-type and said organic semiconductor layer of a second type (8) if present is of a n-type if said organic semiconductor layer of a first type (7) is of a p-type and is of a p-type if said organic semiconductor layer of a first type (7) is of a n-type.
In an embodiment, said organic device may be selected from the list consisting of organic bottom contact transistors, transistor-diodes, Ion Sensitive Field Effect Transistors, Organic Light Emitting Diodes, organic diodes and organic CMOS circuits.
For instance, said organic device may be an organic bottom contact transistor.
As an additional feature, when said organic device is an organic CMOS circuit, step (v) may comprise providing a second surface modification of a first type on some but not all of the electrical contact structures that were protected in step (ii) and providing a second surface modification of a second type on electrical contact structures that were protected in step (ii) and not yet provided with said second surface modification of a first type.
In an embodiment, when said organic device is an organic bottom contact transistor, step (i) may be performed by providing a substrate (1) comprising one or more gate electrodes (2), providing a dielectric layer (3) on said substrate (1) and on said one or more gate electrodes (2), providing contact structures (4) on said dielectric layer (2), wherein said dielectric layer (3) is a gate dielectric layer (3), wherein said contact structures (4) are source and drain electrodes (4); step (ii) may be performed by providing a first temporary protection layer (9) on the free surfaces of some or all of the source and drain electrodes (4); the step (iv) of removing the first temporary protection layer (9) may be performed without removing the first surface modification layer (6) from the gate dielectric layer (3); and the step of providing a second surface modification layer (5) on the electrical contact structures (4) may comprise providing a second surface modification layer (5) on the free surfaces of the source and drain electrodes (4).
In an embodiment of the first aspect, the method may further comprise the encapsulation of said organic device obtained in step (vii).
In a second aspect, the present invention relates to an organic device obtainable by the method of any embodiment of the first aspect of the present invention.
In a further aspect, the present invention relates to a device as obtained after any step, e.g. after an intermediate step, in any method of the present invention.
For instance, in an embodiment, the present invention may relate to a device comprising:
   a substrate (1) having a surface comprising electrical structures (4) and a dielectric portion (3), and
   a first temporary protection layer (9) on some or all of said electrical contact structures.

For instance, in an embodiment of the first aspect, a method for manufacturing organic bottom-contact devices is provided, e.g. organic bottom-contact transistors with a good charge mobility, for example with a charge mobility in the range between 10⁻² cm²/V·s and 6×10⁻¹ cm²/V·s, e.g. in the range between 5×10⁻² cm²/V·s and 3×10⁻¹ cm²/V·s, and/or wherein the method allows realizing a small channel length, e.g. a channel length in the range between 1 micrometer and 10 micrometer, e.g. in the range between 2 micrometer and 5 micrometer.

In a method according to the first aspect, after providing on a substrate a dielectric layer and after providing bottom contact structures, for example by means of a lift-off technique or by any other suitable technique known by a person skilled in the art, a temporary protection layer may be provided on the bottom contact structures. Providing the temporary protection layer can for example be performed during the preparation of the bottom contact structures, for example using a lift-off process. Alternatively, providing the temporary protection layer can be performed in a separate step, after forming the bottom contact structures. After providing the bottom contact structures, an UV-ozone cleaning step may be performed (either before or after providing the temporary protection layer). Next a first surface modification layer, e.g. a silane layer, an organic phosphonic acid layer or a carboxylic acid layer, may be provided at least on the dielectric layer surface. Then the temporary protection layer may be removed by a chemical treatment that does not deteriorate the first surface modification layer, e.g. silane layer. In a next step a second surface modification layer, preferably a SAM, e.g. comprising thiols, organic disulfides, substituted thioureas, isothiocyanates, thiophenes, imidazole-2-thiones, selenols, organic diselenides, nitriles, isonitriles, or thioacetates, may be provided selectively on the bottom contacts. After that, an organic semiconductor layer, e.g. a pentacene layer, with a good morphology and a good mobility can be formed. In preferred embodiments the first temporary protection layer and/or the second temporary protection layer may be selected such that they lead to a hydrophobic surface.

It is an advantage of a method according to embodiments of the present invention that the second surface modification layer (e.g. a self-assembled monolayer, a dopant or a compound (deliberately) made by partial reaction of the bottom contact metal with an electron acceptor) is provided after providing the first surface modification layer (e.g. silane), such that degradation of the second surface modification layer (e.g. a self-assembled monolayer, a dopant or a compound deliberately made by partial reaction of the bottom contact metal with an electron acceptor) by providing the first surface modification layer (e.g. silane) (as in prior art methods) can be avoided.

It is an advantage of a method according to the present invention that the formation of a metal oxide, e.g. gold oxide, on the bottom contact structure, e.g. gold bottom contact structure, can be avoided. In prior art methods such a metal oxide, e.g. gold oxide, may be formed during UV ozone cleaning after formation of the bottom contacts. Avoiding the formation of a metal oxide on the bottom contact structure, e.g. by providing a temporary protection layer as described in embodiments of the present invention, enables the use of lift-off techniques for forming the bottom contacts (without contamination or deterioration by e.g. a metal oxide layer), and thus the realisation of small channel lengths, leading to organic transistors with good performance. A method of the present invention can also be used for fabricating transistors with large channel lengths, e.g. channel lengths up to several hundreds of micrometers.

It is an advantage of a method according to embodiments of the present invention that bottom-contact pentacene transistors comprising contacts based on other materials than gold, e.g. materials that would not withstand the UV-ozone cleaning, e.g. bottom contacts based on Ag, Cu, Ni, . . . , can be fabricated. It is an advantage that the price of these materials is lower than the price of gold, such that cheaper organic circuits could be made. The bottom contacts can comprise a single metal (eventually with an adhesion layer underneath) or the bottom contacts can comprise two or more metals, e.g. a stack of layers comprising different metals or a metal alloy.

In embodiments of the present invention, providing a first surface modification layer preferably converts the surface of the dielectric layer from hydrophilic to hydrophobic. After removing the temporary protection layer, a surface is obtained that is partly hydrophobic and partly hydrophilbic. More in particular, the surface is hydrophobic at locations where the dielectric layer (with the first surface modification layer) is present, and the surface is hydrophilic at locations where the bottom contacts are present (i.e. where the temporary protection layer has been removed). Providing the second surface modification layer then preferably converts the surface of the bottom contacts into a hydrophobic surface, such that the whole surface becomes hydrophobic, enabling the growth of an organic semiconductor layer with a good morphology.

It is an advantage of embodiments of the present invention that, after removing the temporary protection layer and before providing the second surface modification layer, a surface comprising hydrophobic regions (dielectric with first surface modification layer) and hydrophilic regions (bottom contacts) is available. This difference in surface properties can advantageously be used, e.g. for selectively applying the second surface modification layer to the bottom contacts or for selectively applying solutions or liquids comprising reagents to the bottom contacts, wherein the reagents can for example be used for local doping of an organic semiconductor (such as pentacene deposited onto the contacts in a later stage of the process), or for forming an injection layer on the contacts.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein. Further, it is understood that this summary is merely an example and is not intended to limit the scope of the invention. The invention, both as to organization and method of operation, together with features and advantages thereof, may best be understood by reference to the following detailed description when read in conjunction with the accompanying drawings.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 schematically illustrates a bottom contact organic transistor that can be fabricated according to a method of an embodiment of the present invention.

FIG. 2(a) to FIG. 2(e) schematically illustrates a method for fabricating organic transistors according to an embodiment of the present invention.

FIG. 3 schematically illustrates a bottom contact organic transistor with two different kinds of source-drain contacts (injection layers 5 and 10), using the same semiconductor 7, that can be fabricated according to a method of the present invention.

FIG. 4 schematically illustrates a bottom contact organic transistor with two different kinds of source-drain contacts (injection layers 5 and 10) and two different semiconductors (7 and 8), that can be fabricated according to a method of the present invention.

FIG. 5 schematically illustrates a substrate with unprotected source-drain contacts and protected source-drain contacts (4 covered by 9), that can be obtained as an intermediate during a method according to an embodiment of the present invention.

FIG. 6 schematically illustrates a substrate with two different kinds of protection layers (11 and 12) on top of the source-drain contact, that can be obtained as an intermediate during a method according to an embodiment of the present invention.

FIG. 7 schematically illustrates a substrate with source-drain contacts protected by on single protection layer 11 and one double protection layer 12 on 11, that can be obtained as an intermediate during a method according to an embodiment of the present invention.

FIG. 8(a) shows the IDS versus VGS characteristics and FIG. 8(b) shows the IDS versus VDS characteristics for Au bottom contact transistors fabricated according to a method according to an embodiment of the present invention, using a 1,2-BZDMT thiol as a second surface modification layer.

FIG. 9(a) shows the IDS versus VGS characteristics and FIG. 9(b) shows the IDS versus VDS characteristics for Au bottom contact transistors fabricated according to a method according to an embodiment of the present invention, using a 1,3-BZDMT thiol as a second surface modification layer.

FIG. 10 shows the IDS versus VGS characteristics for a Ag bottom contact transistor with silver sulfide injection layer, fabricated according to a method according to an embodiment of the present invention.

FIG. 11(a) shows the IDS versus VGS characteristics and FIG. 11(b) shows the IDS versus VDS characteristics for Pd bottom contact transistors fabricated according to a method according to an embodiment of the present invention, using OTS as a first surface modification layer.

FIG. 12(a) shows the IDS versus VGS characteristics and FIG. 12(b) shows the IDS versus VDS characteristics for Pd bottom contact transistors fabricated according to an embodiment of a method of the present invention, using PETS as a first surface modification layer.

FIGS. 13 and 14 show typical I_{DS} versus V_{GS} characteristics of an Au bottom contact transistor (W/L=5000/10 μm/μm) with phenylethyltrichlorosilane (PETS) based gas phase deposited self-assembled monolayer on the SiOₓ gate dielectric and pentafluorobenzenethiol based self-assembled monolayer on the Au. In FIG. 13, a traditional process according to the prior art was used and in FIG. 14, a process according to an embodiment of the present invention was used.

FIGS. 15 and 16 show typical I_{DS} versus V_{GS} characteristics of an Au bottom contact transistor (W/L=5000/10 μm/μm) with phenylethyltrichlorosilane (PETS) based gas phase deposited self-assembled monolayer on the SiOₓ gate dielectric and diphenyldiselenide based self-assembled monolayer on the Au. In FIG. 15, the traditional process according to the prior art was used and in FIG. 16 a process according to an embodiment of the present invention was used.

FIGS. 17 and 18 show typical I_{DS} versus V_{GS} characteristics for Au bottom contact transistor (W/L=5000/10 μm/μm) with phenylethyltrichlorosilane (PETS) based gas phase deposited self-assembled monolayer on the SiOₓ gate dielectric and bis(pentafluorophenyl)diselane based self-assembled monolayer on the Au. In FIG. 17, the traditional process of the prior art was used and in FIG. 18, a process according to an embodiment of the present invention was used.

FIG. 19 shows the IDS versus VGS characteristics and FIG. 20 shows the IDS versus VDS characteristics for Ag bottom contact transistor (W/L=5000/10 μm/μm) with phenylethyltrichlorosilane (PETS) based gas phase deposited self-assembled monolayer on the SiO₂ gate dielectric and 1,2-benzenedithiol based self-assembled monolayer on the Ag.

FIG. 21 shows the IDS versus VGS characteristics and FIG. 22 shows the IDS versus VDS characteristics for Ag bottom contact transistor (W/L=5000/10 μm/μm) with phenylethyltrichlorosilane (PETS) based gas phase deposited self-assembled monolayer on the SiO₂ gate dielectric and 1,2-benzenedimethanethiol based self-assembled monolayer on the Ag.

FIG. 23 shows the IDS versus VGS characteristics and FIG. 24 shows the IDS versus VDS characteristics for Ag bottom contact transistor (W/L=5000/10 μm/μm) with phenylethyltrichlorosilane (PETS) based gas phase deposited self-assembled monolayer on the SiO₂ gate dielectric and poly(3,4-ethylenedioxythiophene)-poly(styrenesulfonate) was spin coated on the Ag.

FIG. 25 shows the IDS versus VGS characteristics and FIG. 26 shows the IDS versus VDS characteristics for Ag bottom contact transistor (W/L=5000/10 μm/μm) with phenylethyltrichlorosilane (PETS) based gas phase deposited self-assembled monolayer on the SiO₂ gate dielectric and no surface modification layer on the Ag.

In the different drawings, the same reference signs refer to the same or analogous elements.

### DESCRIPTION OF ILLUSTRATIVE EMBODIMENTS

The present invention will be described with respect to particular embodiments and with reference to certain drawings but the invention is not limited thereto but only by the claims.

In the following detailed description, numerous specific details are set forth in order to provide a thorough understanding of the invention and how it may be practiced in particular embodiments. However, it will be understood that the present invention may be practiced without these specific details. In other instances, well-known methods, procedures and techniques have not been described in detail, so as not to obscure the present disclosure. While the present invention will be described with respect to particular embodiments and with reference to certain drawings, the invention is not limited hereto. The drawings included and described herein are schematic and are not limiting the scope of the invention. It is also noted that in the drawings, the size of some elements may be exaggerated and, therefore, not drawn to scale for illustrative purposes.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B.

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

The invention will now be described by a detailed description of several embodiments of the invention. It is clear that other embodiments of the invention can be configured according to the knowledge of persons skilled in the art without departing from the true spirit or technical teaching of the invention, the invention being limited only by the terms of the appended claims.

Reference will be made to transistors. These are three-terminal devices having a first main electrode such as a drain, a second main electrode such as a source and a control electrode such as a gate for controlling the flow of electrical charges between the first and second main electrodes.

The method of the present invention is further described for an exemplary embodiment wherein the method is used for the fabrication of organic bottom contact transistors. However, the method of the present invention can also be used in a fabrication process of other devices, such as for example transistor-diodes (transistors wherein the gate and the drain are electrically connected), or for example ISFETs (Ion Sensitive Field Effect Transistors), or for example OLEDs (Organic Light Emitting Diodes), or for example organic diodes.

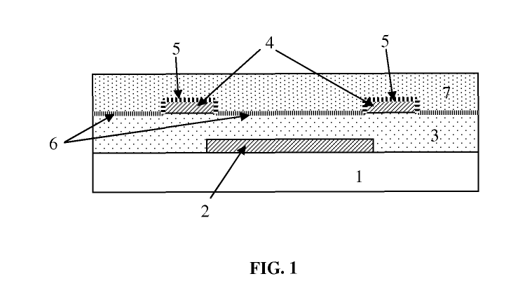

FIG. 1 schematically illustrates the structure of a bottom contact organic transistor that can be fabricated according to a method according to an embodiment of the present invention. The bottom contact organic transistor comprises, on a substrate 1, a gate electrode 2 and a gate dielectric layer 3. On top of the gate dielectric layer 3, source and drain electrodes 4 are present, the surfaces of the source and drain electrodes that are not in contact with the gate dielectric layer 3 being covered by a second surface modification layer 5. Surfaces of the gate dielectric layer 3 at locations where no source or drain electrodes are present are covered with a first surface modification layer 6. On top of the first surface modification layer 6 and the second surface modification layer 5 an organic semiconductor layer 7 is present.

A method for fabricating organic devices, e.g. organic transistors, according to an embodiment of the present invention may comprise: providing on a substrate a dielectric layer; providing bottom contact structures on the dielectric layer; providing a temporary protection layer on the bottom contact structures; providing a first surface modification layer on the dielectric layer; removing the temporary protection layer; providing a second surface modification layer on the bottom contact structures; and providing an organic semiconductor layer.

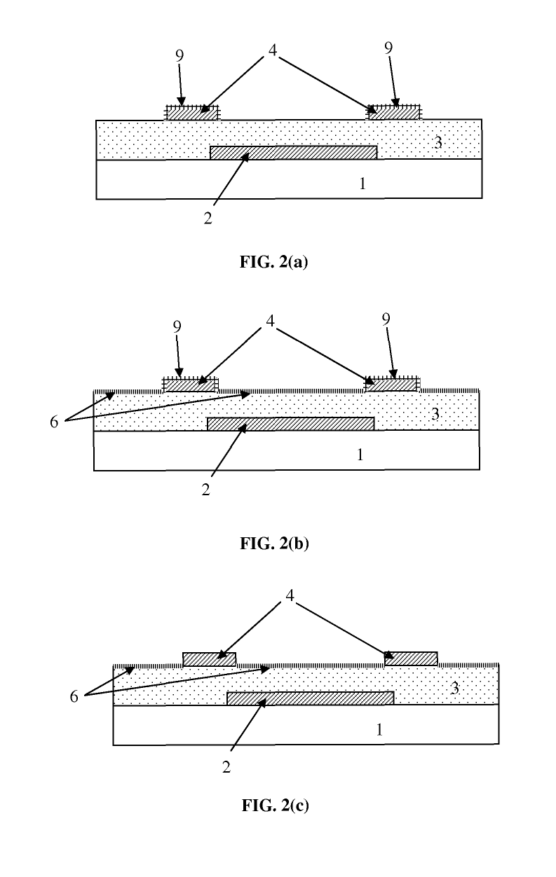

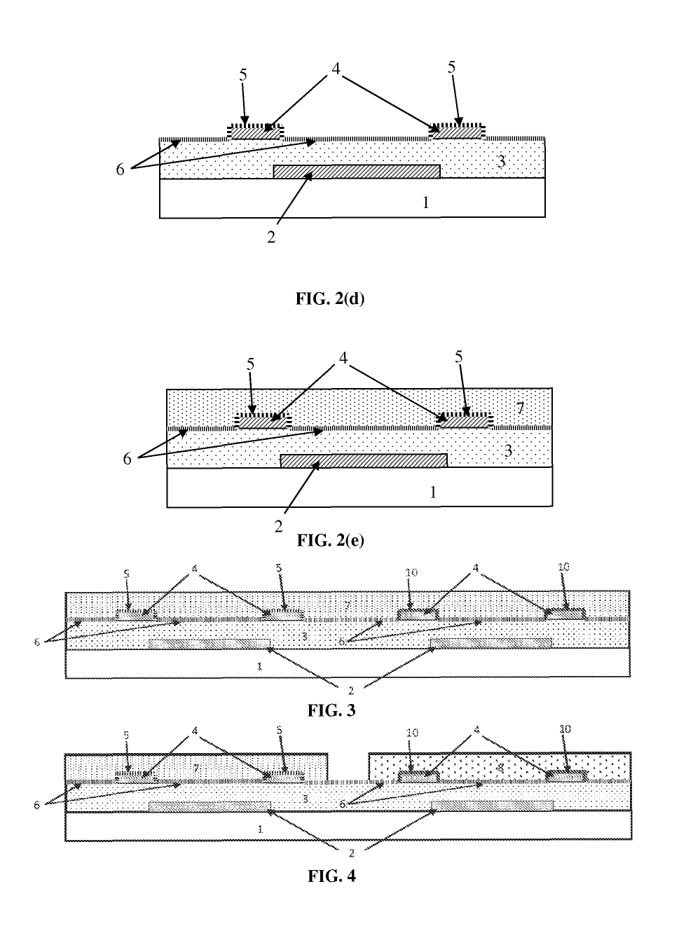

FIG. 2 schematically illustrates a method for fabricating organic transistors according to an embodiment of the present invention. After forming on a substrate 1 a gate electrode 2 and a gate dielectric layer 3, source and drain electrodes 4 are provided on the gate dielectric layer 3. Next, as illustrated in FIG. 2(a), a temporary protection layer 9 is provided on the free surfaces of the source and drain electrodes 4, i.e. on the surfaces of the source and drain electrodes 4 that are not in contact with the gate dielectric layer 3. A first surface modification layer 6 is then provided on the free surfaces of the gate dielectric layer (FIG. 2(b)). Next the temporary protection layer 9 is removed (including a first surface modification layer 6 that may have been formed on top of the temporary protection layer 9) (FIG. 2(c)) without removing the first surface modification layer 6 from the gate dielectric layer 3, and a second surface modification layer 5 is provided (FIG. 2(d)) on the free surfaces of the source and drain electrodes 4 (where the temporary protection layer 9 has been removed). Next, as shown in FIG. 2(e) an organic semiconductor layer 7 is provided.

Providing the temporary protection layer can for example be performed during the preparation of the bottom contact structures using a lift-off process. Alternatively, providing the temporary protection layer can be performed in a separate step, after forming the bottom contact structures, for example by electrodeposition or by electroless deposition. The temporary protection layer can comprise a metal, such as for example Al, Cu, Mg, Zn, Ti, Zr or Hf, or it can comprise an organic or an inorganic material such as for example a polymer or metal salt or a metal oxide. The temporary protection layer can be a single layer or it can be a stack of two or more layers.

The first surface modification layer can for example comprise or consist of a silane, an organic phosphonic acid or a carboxylic acid. Application of the first surface modification layer may for example comprise reaction of the surface with a vapour or with a (diluted) solution of the reagent, spin coating or spray coating.

The temporary protection layer is preferably removed by a chemical treatment that does not deteriorate the first surface modification layer, e.g. silane layer. For example, with Au, Pt, Pd, Ag or Cu bottom contacts a temporary protection layer comprising e.g. Al, Mg or Zn can be removed by means of a diluted hydrochloric or sulphuric acid. For example, with Au, Pt or Pd bottom contacts a Cu protection layer can be removed by a diluted nitric acid. Preferably the chemical treatment used for removing the temporary protection layer does not lead to an oxidation of the bottom contacts.

The second surface modification layer can for example comprise or consist of a thiol, an organic disulfide, substituted thiourea, isothiocyanate, thiophene, imidazole-2-thione, selenol, organic diselenide, thioacetate, a nitrile or an isonitrile. The second surface modification layer is preferably thin (such that good charge injection can be maintained), it is preferably reproducible and homogeneous. Therefore, in preferred embodiments, the second surface modification layer can be a SAM (Self-Assembled Monolayer). The second surface modification layer can also for example comprise a chemical compound made by partial reaction of the bottom contact metal with an electron acceptor, or for example a chemical compound or mixture of compounds acting as a dopant for the semiconductor at the bottom contact—semiconductor interface or improving charge injection into the semiconductor at the bottom contact—semiconductor interface.

In embodiments of the present invention, the term “substrate” may include any underlying material or materials that may be used, or upon which an organic layer or a device may be formed in accordance with embodiments of the present invention. The term “substrate” is thus used to define generally the elements for layers that underlie a layer or portions of interest. The substrate may be a rigid substrate or a flexible substrate. Examples of rigid substrates are plastic, glass, steel, aluminium and semiconductor substrates such as e.g. Si, GaAs or SiC substrates. Flexible substrates that may be used are for example PEN foil, PET foil, paper. The list of substrates is not intended to be restrictive, but only to provide examples.

### Example 1

### Au Bottom Contact Transistors

Au bottom-contact organic transistors were prepared by a fabrication process using lift-off for the formation of the bottom metal contacts. In the experiments, silicon substrates comprising a common aluminum gate and a 140 nm thick dielectric layer (silicon dioxide) were used. After cleaning of the substrate a patterned photoresist layer was provided, followed by a metallization step comprising sputtering of a 20 nm thick gold layer and a 5 nm thick aluminum layer. Next a lift-off step was performed in an ultrasonic bath with acetone. In the transistor structure, the 20 nm thick gold layer forms the source and the drain of the transistor. The 5 nm aluminum layer acts as a temporary protection layer in accordance with an embodiment of the present invention.

After wet cleaning and UV-ozone cleaning (15 minutes) of the samples, a silane treatment was performed wherein PETS (phenylethyltrichlorosilane) was provided from the vapor phase at a temperature of 140° C. during 30 minutes (first surface modification layer). Next the 5 nm thick aluminum protection layer was removed by reaction with diluted hydrochloric acid (1 volume concentrated HCl+5 volumes H₂O) during 10 minutes, followed by rinsing in water. Next a SAM deposition step was performed for providing a second surface modification layer on the Au bottom contacts. For a first group of samples, a thiol (1,2-BZDMT, 1,2-benzenedimethanethiol) was provided from ethanol solution during 1200 minutes. For a second group of samples another thiol (1,3-BZDMT, 1,3-benzenedimethanethiol) was provided from ethanol solution during 1200 minutes. Next the samples were cleaned and a pentacene layer was grown by means of OMBD.

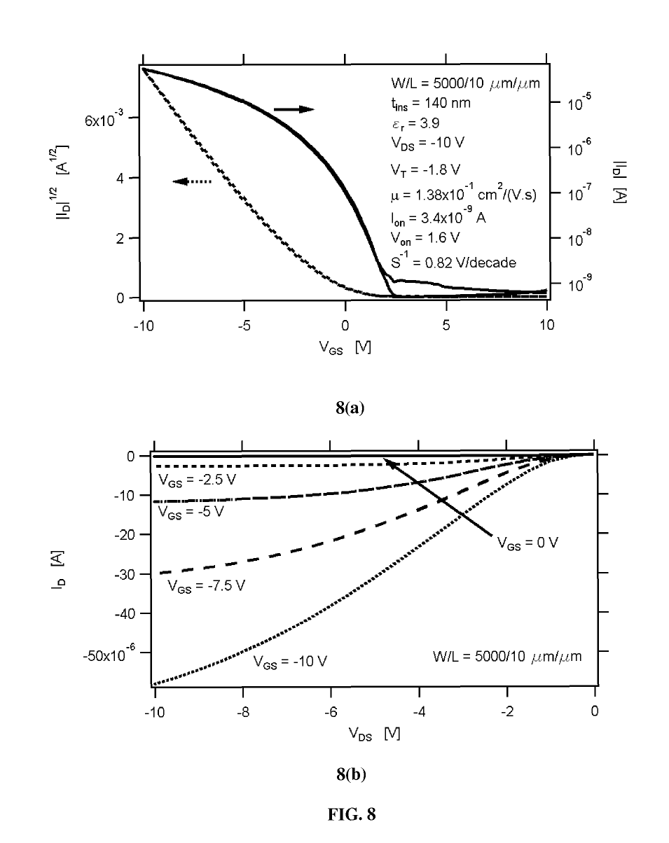

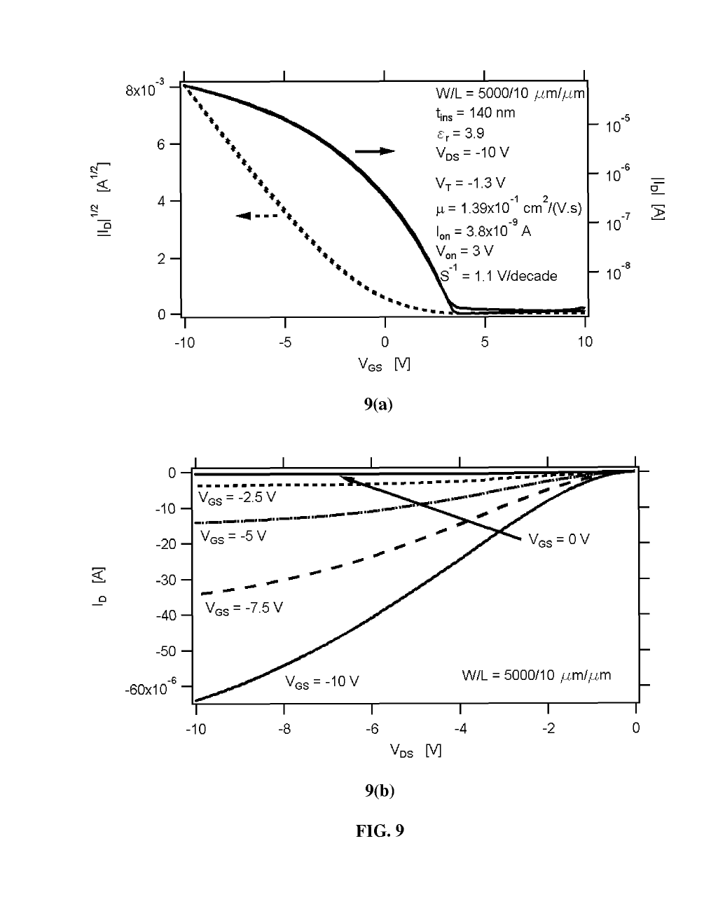

The current-voltage characteristics of the resulting transistor devices were measured. FIG. 8(a) shows the IDS versus VGS characteristics and FIG. 8(b) shows the IDS versus VDS characteristics for transistors fabricated with 1,2-BZDMT (first group of samples as described above). FIG. 9(a) shows the IDS versus VGS characteristics and FIG. 9(b) shows the IDS versus VDS characteristics for transistors fabricated with 1,3-BZDMT (second group of samples as described above). From these current-voltage characteristics it can be concluded that good transistors can be fabricated using a method according to an embodiment of the present invention. The mobilities reached (about 0.14 cm²/Vs) can be further improved by modification of the process (e.g. by using other SAMs).

### Example 2

### Ag Bottom Contact Transistors

Experiments were performed wherein Ag bottom contact transistors were fabricated according to a method according to an embodiment of the present invention. A metallization step was performed comprising providing a stack of a 15 nm thick Au layer (acting as an adhesion layer) and a 20 nm thick Ag layer (acting as bottom contact metal from which also an “injection layer” can be made by partial chemical reaction between the silver and an electron acceptor). Next a 5 nm thick Al protection layer was provided on the Ag layer. Patterning of the Au adhesion layer, the Ag layer and the Al protection layer was performed using a single lift-off step. After UV-ozone cleaning and silanization (formation of a first surface modification layer), the Al protection layer was removed by reaction with diluted hydrochloric acid (1 volume concentrated HCl+5 volumes H₂O) during 10 min. Next the surface of the Ag layer was modified by a chemical reaction with an electron acceptor (sulfur). This gives rise to a silver sulfide layer (second surface modification layer) at the surface of the Ag contacts, creating an “injection layer”. In the context of the present invention, an injection layer is a layer favoring charge injection from the bottom contact metal into the organic semiconductor.

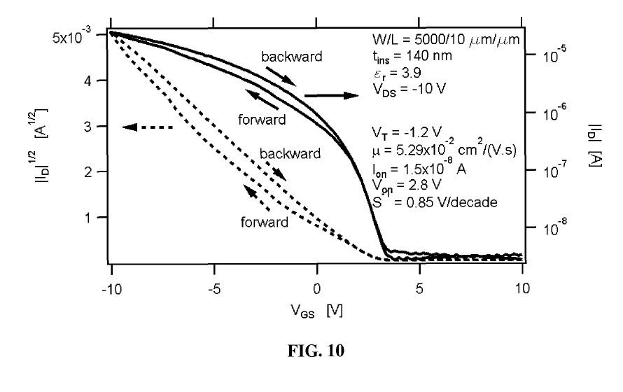

Preliminary results of electrical measurements (IDS versus VGS characteristics) are shown in FIG. 10. The characteristics of the best transistor resulting from the experiments described above are shown in FIG. 10. A hysteresis between the forward scan and the backward scan was observed. According to the results, the transistor properties deteriorate with increasing reaction time (and thus increasing silver sulfide layer thickness). The transistor characteristics of these Ag bottom contact transistors may be further improved by reducing the reaction time between the sulfur and the Ag and thus by reducing the thickness of the silver sulfide layer.

### Example 3

### Pd Bottom Contact Transistors

Experiments were performed wherein Pd bottom contact transistors were fabricated according to a method according to an embodiment of the present invention. A metallization step was performed comprising providing a stack of a 5 nm thick TiW layer (acting as an adhesion layer) and a 20 nm thick Pd layer (acting as bottom contact metal). Next a 5 nm thick Al protection layer was provided on the Pd layer. After UV-ozone cleaning and silanization (forming a first surface modification layer), the Al protection layer was removed by reaction with diluted sulfuric acid (1 volume concentrated H₂SO₄+5 volumes H₂O) during 10 minutes. For the silanization step, two different silanes were used: for one group of transistors OTS (octadecyltrichlorosilane) was used as a first surface modification layer, and for another group of transistors PETS (phenylethyltrichlorosilane) was used as a first surface modification layer.

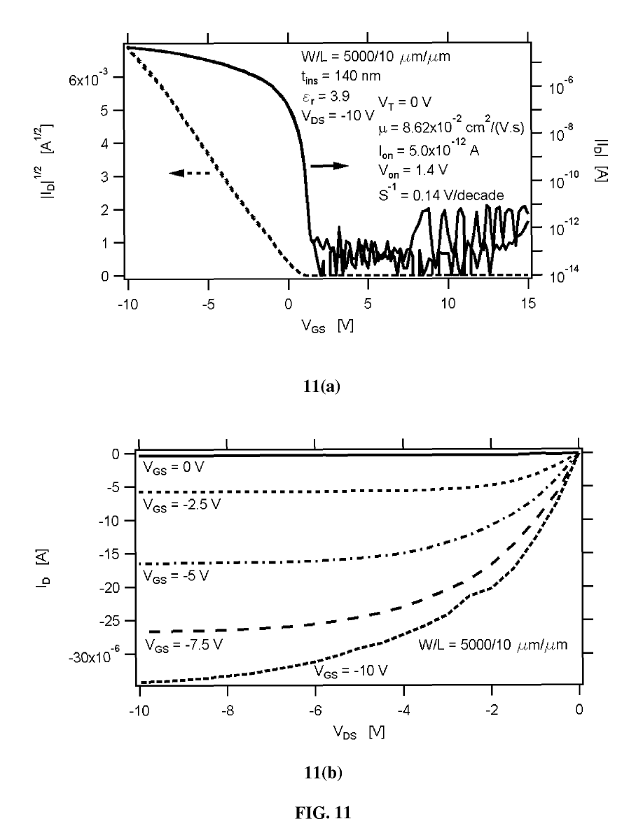

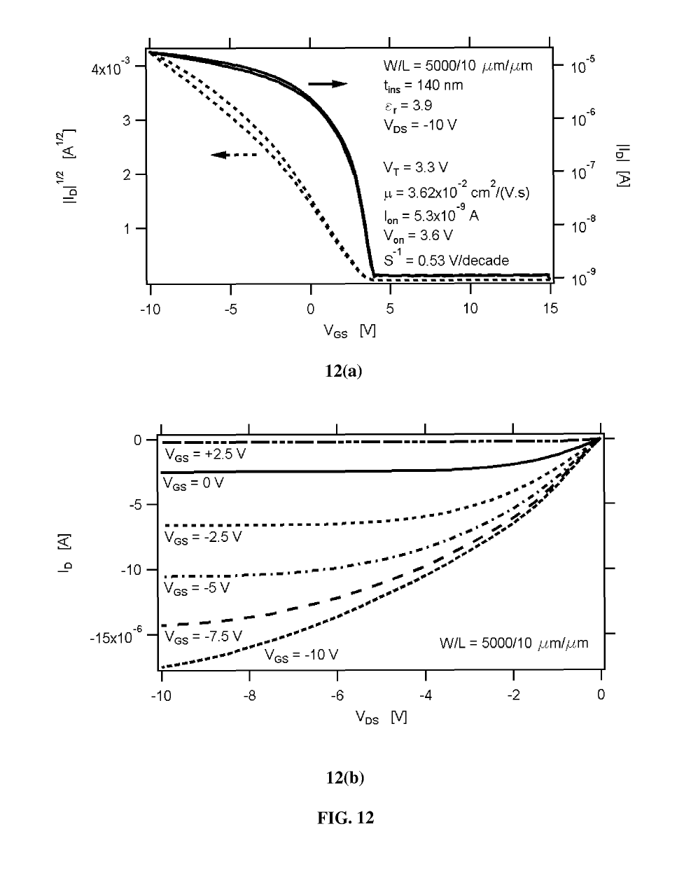

FIG. 11(a) shows the IDS versus VGS characteristics and FIG. 11(b) shows the IDS versus VDS characteristics for Pd bottom contact transistors fabricated according to a method according to an embodiment of the present invention, using OTS as a first surface modification layer. FIG. 12(a) shows the IDS versus VGS characteristics and FIG. 12(b) shows the IDS versus VDS characteristics for Pd bottom contact transistors fabricated according to a method according to an embodiment of the present invention, using PETS as a first surface modification layer.

The measurement results show a higher mobility for transistors fabricated according to a method according to an embodiment of the present invention as compared to transistors fabricated according to a prior art method. A possible explanation can be that this may be related to the formation of palladium oxide during the UV-ozone treatment when using a prior art fabrication method, while using a temporary protection layer according to an embodiment of the present invention may avoid formation of such an oxide.

A further advantage of using a protection layer according to an embodiment of the present invention is that it allows using a second surface modification layer (e.g. nitriles, isonitriles) in combination with a first surface modification layer (e.g. silanes, phosphonic acids, . . . ).

### Example 4

### Protection Layers

Further experiments were performed with a Cu protection layer. These experiments were performed on blanket substrates (no transistors were made) to check if Cu can be used as a protection layer in a method according to an embodiment the present invention. The suitability of Cu as a protection layer was evaluated by testing if there is a difference in hydrophobicity between the metal (after removal of the Cu protection layer) and the silane layer on the surrounding SiO₂. The following steps were performed: evaporation of a 50 nm thick Au layer (metallization), sputtering of a 10 nm thick Cu layer (protection layer), UV-ozone cleaning, silanization and removal of the Cu protection layer with diluted nitric acid (1 volume concentrated HNO₃+10 volumes H₂O) using a (not optimized) reaction time of 15 and 30 minutes. From these experiments it could be concluded that there is indeed a difference in hydrophobicity between the metal and the silane layer on the dielectric layer, and that Cu is a good protection layer. Cu may also be used to protect other metals such as for example Au, Pt or Pd.

Protection Layers: General Considerations

Other materials can be used for forming the temporary protection layer in embodiments of the present invention, such as for example Mg, Zn, Ti, Zr or Hf, or an organic or an inorganic material such as for example a metal salt or a metal oxide that has a sufficient adhesion to the bottom contact metal, is compatible with the processing (e.g. lift-off), and can be removed afterwards without affecting the first surface modification layer. Also mixtures or combinations of these materials can be used for forming the temporary protection layer. The material used for forming the temporary protection layer preferably does not react with the bottom contact metal and preferably does not modify or contaminate the bottom contact metal. Preferably the temporary protection layer can be removed without attacking the bottom contact metal. For example, an Al protection layer on Au, Pd, Ag and Pt can be removed by diluted HCl, H₂SO₄, . . . acids which are not attacking the bottom contact metal. For example, a Cu protection layer on Au can be removed by diluted HNO₃ whereas a Cu protection layer on Ag cannot be removed by diluted HNO₃ because the HNO₃ may also attack the Ag.

In embodiments of the present invention, the temporary protection layer can be formed during the preparation of the bottom contact structures using a lift-off process, as in the experiments described above. However, in embodiments of the present invention the temporary protection layer be provided after finishing the formation of bottom contacts. For example, the temporary protection layer may be provided by means of an electrodeposition process (requiring electrical connection to all bottom contacts). The material to be electrodeposited may be a metal or a polymer (e.g. made directly by electrochemical polymerization from its monomer). In case of a polymer, electrodeposition may be performed from an aqueous monomer solution and removal of the temporary protection layer may involve dissolution of the polymer in an organic solvent.

Removal of a metal temporary protection layer may be performed with diluted acids as described above. In some embodiments, for example when using aluminum as a temporary protection layer, the temporary protection layer can be removed by a diluted base. Alternatively, removal of a metal temporary protection layer may also be performed on selected bottom contact structures by an electrochemical process. Such a process would require that the bottom contact metal is more “noble” than the protection layer metal.

A method according to embodiments of the present invention can be used for providing surface modifications of the bottom contact aiming at improving charge injection (decreased contact resistance), as e.g. illustrated above for transistors with Ag bottom contacts, where a silver sulfide is formed for improving carrier injection. This method can also be used with copper bottom contacts, wherein a charge-transfer complex such as CuTCNQ (where TCNQ stands for tetracyanoquinodimethane) can be grown by a chemical reaction from the copper bottom contacts. In prior art processes CuTCNQ is used without a silane layer on the dielectric layer, because CuTCNQ may be chemically attacked during the silanization step. In embodiments of the present invention the following process sequence can be used: providing a dielectric layer and Cu bottom contacts; providing a temporary protection layer on the Cu bottom contacts, providing a first surface modification layer (e.g. silanization) on the dielectric layer surface, removing the temporary protection layer from the Cu bottom contacts, providing TCNQ on the bottom Cu contacts for forming CuTCNQ and finally growing an organic semiconductor layer. Similar methods can be used for other charge-transfer complexes (e.g. AgTCNQ) and other ionic salts (e.g. copper chalcogenides and silver chalcogenides).

A method according to an embodiment of the present invention may also be used for selective doping of the contacts (i.e. doping of the contacts and no doping in the channel), aiming at improving charge injection from the contacts into the organic semiconductor. This may for example be accomplished via solution processing (for example spin coating or dip coating). After removal of the temporary protection layer, gold bottom contacts are hydrophilic whereas the dielectric in the channel became hydrophobic due to the silane treatment. When dipping the sample in a solution (liquid) or when coating the sample with a liquid, the liquid (e.g. comprising TCNQ) may only stay on the hydrophilic Au bottom contacts and not on the hydrophobic dielectric surface. Letting evaporate the solvent would then lead to a thin layer (e.g. TCNQ) on the Au. The TCNQ can for example serve as a local dopant for pentacene transistors.

Similarly, a soluble charge-transfer complex (for example TTF-TCNQ (wherein TTF stands for tetrathiafulvalene) may be locally deposited on the contacts by spin-coating or dip-coating.

A method according to an embodiment of the present invention may also be used in a process for making organic CMOS circuits. In this case, for instance, two different dopants or charge-transfer complexes can be ink-jetted (using a print-head with two different nozzles) on different bottom contacts, with an ink solution that has an affinity for the hydrophilic bottom contacts and not for the hydrophobic silane surface on the dielectric layer.

### Example 5

### Application of the Invention to the Fabrication of Transistors with Different Properties (for Example for CMOS Circuits)

The method according to embodiments of the present invention can also be used for the preparation of substrates with two different kinds of transistors with some differences in electrical properties (FIG. 3) or CMOS type as shown in FIG. 4 (8=other semiconductor, for example if 7=p-type then 8=n-type and vice-versa).

Principle:

In an embodiment of the invention a protection layer is only present on a part of the bottom S/D contacts of bottom gate transistors. This can for example be realized by performing two successive photolithographical steps with 2 different metallizations: one metallization of a part of the S/D contacts without protection layer and another metallization of a part of the S/D contacts with an additional protection layer (9). Alternatively, depending upon the mask (and circuit) design only one photolithographical step is required; the difference in metallization being obtained by first depositing the S/D bottom contact metal everywhere, and then selectively masking (e.g. by a shadow mask) the areas of the substrate before deposition of the protection layer (this has to be done before lift-off or etching). Alternatively, also using only one photolithographical step, the S/D contact metal plus the protection layer is deposited everywhere, with consequent partial removal of the protection layer on selected places (for example by dipping only a restricted portion of the wafer into an etchant solution).

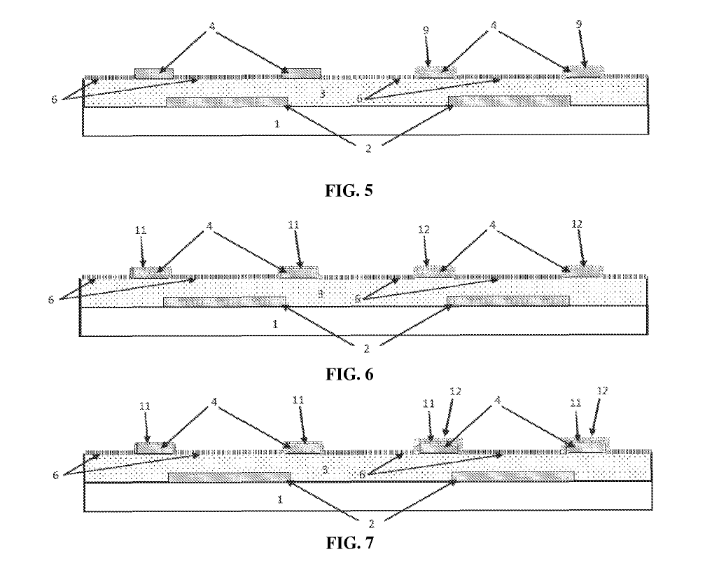

After having prepared substrates with protected and unprotected S/D bottom contacts on the same wafer (or die) as illustrated in FIG. 5, the processing is continued as follows. First the substrates are cleaned by solvent cleaning, and—if not incompatible with the chemical stability of the S/D metallization—the substrate is furthermore cleaned by UV/O3 or oxygen plasma etc. Then a first self-assembled monolayer 5 is deposited (from solution or gas phase) onto the unprotected S/D bottom contact. Afterwards the protection 9 of the protected S/D bottom contact is removed (typically from solution) without removing the self-assembled monolayer 5. Then the substrate is brought into presence with a compound forming a second self-assembled monolayer 10 selectively onto the now unprotected metal, and without significantly affecting the first self-assembled monolayer 5 (no or limited exchange reaction). After solvent based cleaning of the substrates (short rinsing), optional deposition of another self-assembled monolayer onto the gate dielectric, one semiconductor 7 is deposited (FIG. 3) and (after optional encapsulation) the transistors are measured. In another embodiment two different semiconductors can be evaporated (using shadow masking) selectively onto the 2 kinds of bottom contacts (FIG. 4).

Here below are general considerations on how to solve the possible issue of an exchange reaction of the self-assembled monolayers.

Different strategies can be employed for the selective deposition of a second surface modification layer (e.g. self-assembled monolayer SAM2) without significant replacement of the first surface modification layer (e.g. self-assembled monolayer SAM1):
second surface modification layer (e.g. SAM2) can be selected so that the bond strength with the metal is lower than the bond strength of first surface modification layer (e.g. SAM1) to the metal (difference in thermodynamic stability of the first surface modification layer (e.g. SAM1)-metal and second surface modification layer (e.g. SAM2)-metal bond)
first surface modification layer (e.g. SAM1) bond to the metal can form such a dense layer that a replacement by second surface modification layer (e.g. SAM2) would only occur very slowly compared to the fixation of second surface modification layer (e.g. SAM2) on the bare metal (difference in reaction kinetics)
the substrate can be brought into contact with second surface modification layer (e.g. SAM2) gas, this might slow down the kinetics of exchange between first surface modification layer (e.g. SAM1) and second surface modification layer (e.g. SAM2)

Possible process flow (illustrating FIG. 3 and FIG. 4):

1. preparation of bottom gate bottom contact transistors with Au as metal

2. partly cover selected S/D contacts by an aluminum protection layer

3. clean: rinsing acetone, IPA, cleaning with UV/O₃

4. deposition of the gate dielectric (optional, eg. silane on SiO₂)

5. deposition of SAM1 in a way that avoids removal of the protection layer (some solutions of thiols can be sufficiently acid in order to attack aluminum). Possibility 1: deposit SAM1 (for example a thiol) from gas phase (should avoid complete attack of aluminum) Possibility 2: use an organic disulfide or diselenide (alkyldisulfide, aryldisulfide, alkyldiselenide, aryldiselenide, etc); in contrast to thiols (and selenols) disulfides and diselenide typically don't possess acid hydrogens which could attack the protection layer.

5′ optional rinsing

6. remove the protection layer with a diluted acid, sufficiently diluted in order to avoid attack of SAM1 fixed on the metal; if aluminum is used as protection layer a diluted base might also work

6′ optional rinsing

7. deposition of SAM2 onto the bare metal from solution or gas phase without removal of SAM1 (might be possible for example if diphenyldisulfide is used in order to make phenylsulfide-Au bonds (SAM1) and pentafluorobenzenethiol from ethanol solution as SAM2; explanation: fluorine atoms are strongly electronegative and will attract the binding electrons of the S—Au bond more to the S than in absence of fluorine atoms; therefore the S—Au bond should be weaker for the fluorinated molecule)

7′ optional rinsing

8. deposition of self-assembled monolayer onto the dielectric (optional, if not yet done under point 4)

9. deposition of one semiconductor (FIG. 3) or two different semiconductors (FIG. 4).

In a further embodiment of the invention two different protection layers may be used, protecting the S/D bottom contact metal against possible changes which might occur during modification of the dielectric by a self-assembling monolayer (e.g. silane on SiO₂). The substrates can be made by depositing a first protecting layer 11 on one group of S/D bottom contacts and a second (different) protection layer 12) on the other S/D bottom contacts as shown in FIG. 6. The second protection layer can also be deposited on top of the first protection layer as illustrated in FIG. 7. This kind of protection might for example be useful if one of the protection layer materials would for example suffer from a cleaning step involving UV/O₃. In this case an additional protection layer could be deposited on top of the first protection layer.

For example Au S/D bottom contact substrates can be made so that a part of the bottom contacts are covered by aluminum and the others by copper (similar to FIG. 6), or all by copper and in addition some of them by aluminum (similar to FIG. 7). After solvent cleaning and exposure to UV/O₃, a self-assembled monolayer is deposited onto the gate dielectric (e.g. silane). Then, the aluminum is removed by diluted acid which does not corrode copper (eg. diluted hydrochloric or diluted sulfuric acid) or a solution of a base (for example aqueous sodium hydroxide). Then a self-assembled monolayer (for example a thiol) is deposited onto the bare Au bottom contacts. Afterwards the copper protection layer on the remaining Au S/D bottom contacts is removed by treatment with diluted nitric acid. Then, another self-assembled monolayer (e.g. from a thiol or a disulfide) is deposited onto the now unprotected Au bottom contacts. Deposition of a single semiconductor would then lead to 2 kinds of transistors with different electrical properties, whereas in the case were a p-type semiconductor and a n-type semiconductor are deposited selectively (using for example shadow mask techniques) onto transistors with different self-assembled monolayers on the bottom contacts, building blocks of a CMOS circuit could be made.

In another embodiment of the invention multiple protection layers can be used in order to permit selective deprotection. For example on the same substrates there could be 3 different kinds of bottom contacts: unprotected metal, metal protected by an aluminum protection layer, and metal protected by a copper protection layer. This could allow the following process (after cleaning and optional deposition of a SAM onto the gate dielectric): deposition of SAM1 on the bare metal, selective deprotection of the metal protected by Al (for example with diluted hydrochloric or sulfuric acid which does not attack copper), deposition of SAM2 onto the now unprotected metal, deprotection of the metal protected by Cu (with diluted nitric acid; might give limit the choice of SAM1 and SAM2 since they have to be stable against this acid), deposition of SAM3, deposition of a SAM onto the dielectric (optional), deposition of the semiconductor(s).

### Example 6

### Improvement of Pentacene Bottom Contact Transistor Properties

The improvement of pentacene bottom contact transistor properties obtained according to embodiments of the present invention was illustrated by a comparison of the pentacene transistors as obtained by classical methods of the prior art with self-assembled organosulfur or organoselenium monolayers on the gold bottom contact and a self-assembled silane monolayer on the SiOₓ gate dielectric. Such transistors were prepared in 2 different ways: (a) the “prior art” way by solution deposition of the organosulfur or organoselenium self-assembled monolayers on the gold bottom contacts followed by gas phase deposition of a silane based self-assembled monolayer on the SiOₓ gate dielectric, and (b) a method according to an embodiment of the present invention wherein the sequence of each deposition of self-assembled monolayer is reversed (using an additional surface modification layer on the Au bottom contact during the silanization step).

### EXPERIMENTAL

Au bottom-contact organic transistors were prepared by a fabrication process using lift-off for the formation of the bottom metal contacts. In the experiments, silicon substrates comprising a common aluminum gate and a 140 nm thick dielectric layer (silicon dioxide) were used. After cleaning of the substrate a patterned photoresist layer was provided, followed by a metallization step comprising sputtering of a 50 nm thick gold layer and a 5 nm thick aluminum layer. Next a lift-off step was performed in an ultrasonic bath with acetone. In the transistor structure, the 50 nm thick gold layer forms the source and the drain of the transistor. The 5 nm aluminum layer acts as a temporary protection layer in accordance with an embodiment of the present invention. After wet cleaning and UV-ozone cleaning (15 minutes) of the samples, a silane treatment was performed wherein PETS (phenylethyltrichlorosilane) was provided from the vapor phase at a temperature of 140° C. during 30 minutes (first surface modification layer). Next the 5 nm thick aluminum protection layer was removed by reaction with diluted hydrochloric acid (1 volume concentrated HCl+5 volumes H₂O) during 10 minutes, followed by rinsing in water. Next a SAM deposition step was performed for providing a second surface modification layer on the Au bottom contacts. Three different kinds of self-assembled monolayers were tested: (a) pentafluorobenzenethiol (C₆H₅SH, fixing by Au—S—C₆F₅ bonds) deposited from a 10 millimolar solution of pentafluorobenzenethiol in ethyl alcohol (1 hour reaction time), (b) diphenyldiselenide (C₆H₅—Se—Se—C₆H₅, fixing by Au—Se—C₆H₅ bonds) deposited from a 5 millimolar solution in acetonitrile (4 hours deposition time), and (c) bis(pentafluorophenyl)diselane (C₆F₅—Se—Se—C₆F₅, fixing by Au—Se—C₆F₅ bonds) deposited from a 5 millimolar solution in acetonitrile (4 hours deposition time). After deposition the substrates were rinsed with the absolute ethyl alcohol and carefully dried with a nitrogen flow. Then a pentacene layer was grown by means of OMBD.

For comparison, pentacene transistors according to the prior art (made with Au\SiOₓ substrates, with an organosulfur or organoselenium monolayer deposited as described under (a) to (c), followed by silanization with PETS at 140° C. during 30 minutes) were prepared.

For all investigated combinations (see Table 1) the mobility of pentacene transistors prepared according to embodiments of the present invention are higher than with the processing according to the prior art.

TABLE 1
Mobilities and threshold voltages of pentacene transistors W/L = 5000/10 (μm/μm)
prepared with various self-assembled monolayers on Au bottom contacts and
silanization with PETS (140° C., 1 h) according to the prior art process
and according to embodiments of the present invention.

| | Mobility (μ) | | Threshold voltage (V_{T}) | |
|---|---|---|---|---|
| | (cm²/(V · s)) | | (V) | |
| | comparative | embodiment | comparative | embodiment |
| Au—S—C₆F₅ | 0.129 ± 0.014 | 0.249 ± 0.029 | −1.91 ± 0.15 | −2.52 ± 0.24 |
| Au—Se—C₆H₅ | 0.205 ± 0.012 | 0.260 ± 0.020 | −2.34 ± 0.11 | −1.90 ± 0.13 |
| Au—Se—C₆F₅ | 0.159 ± 0.006 | 0.263 ± 0.033 | −3.47 ± 0.10 | −2.44 ± 0.16 |

Indicated values are given as mean value ± standard deviation obtained during measurements of 5 different transistors on the same substrate.

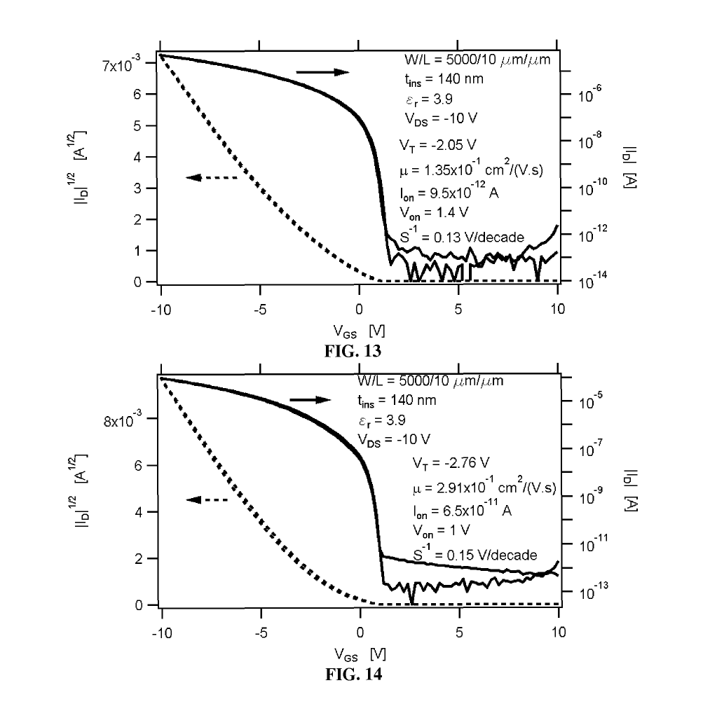

FIGS. 13 and 14 show typical I_{DS} versus V_{GS} characteristics of an Au bottom contact transistor (W/L=5000/10 μm/μm) with phenylethyltrichlorosilane (PETS) based gas phase deposited self-assembled monolayer on the SiOₓ gate dielectric and pentafluorobenzenethiol based self-assembled monolayer on the Au. In FIG. 13, a traditional process according to the prior art was used and in FIG. 14, a process according to an embodiment of the present invention was used.

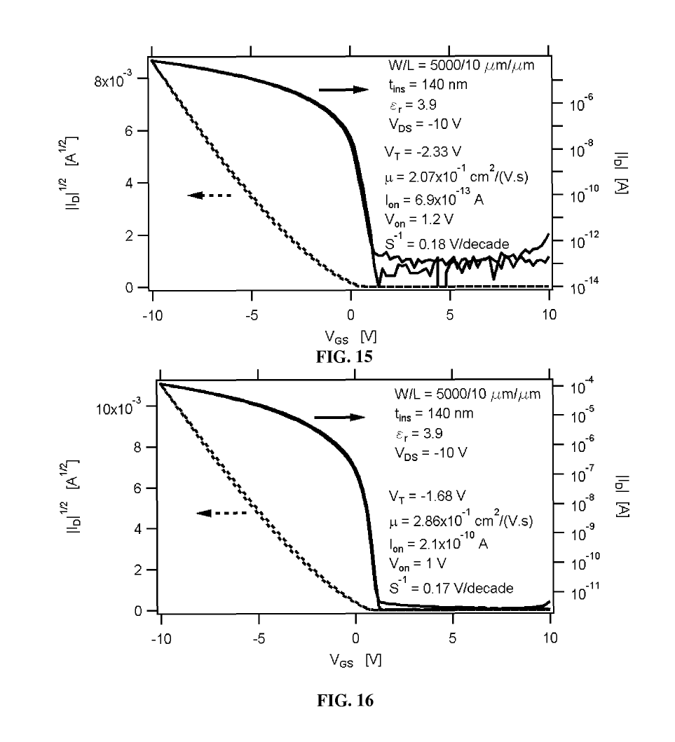

FIGS. 15 and 16 show typical I_{DS} versus V_{GS} characteristics of an Au bottom contact transistor (W/L=5000/10 μm/μm) with phenylethyltrichlorosilane (PETS) based gas phase deposited self-assembled monolayer on the SiOₓ gate dielectric and diphenyldiselenide based self-assembled monolayer on the Au. In FIG. 15, the traditional process according to the prior art was used and in FIG. 16 a process according to an embodiment of the present invention was used.

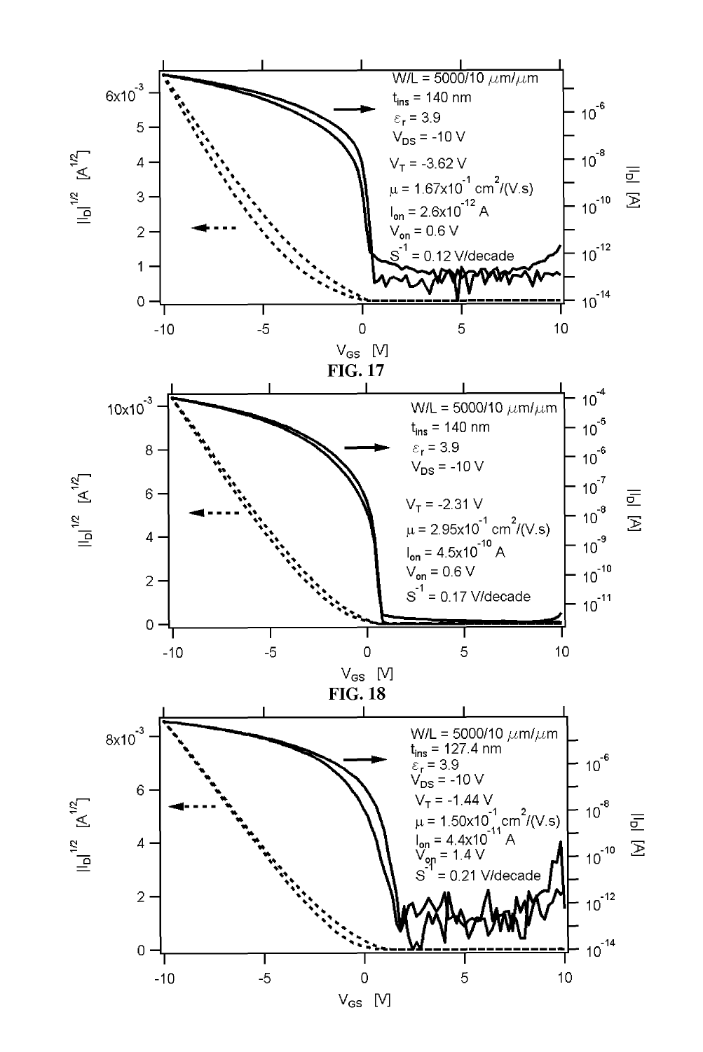

FIGS. 17 and 18 show typical I_{DS} versus V_{GS} characteristics for Au bottom contact transistor (W/L=5000/10 μm/μm) with phenylethyltrichlorosilane (PETS) based gas phase deposited self-assembled monolayer on the SiOₓ gate dielectric and bis(pentafluorophenyl)diselane based self-assembled monolayer on the Au. In FIG. 17, the traditional process of the prior art was used and in FIG. 18, a process according to an embodiment of the present invention was used.

### Example 7

Samples were prepared according to the method described previously in this patent application. Transistor substrates with Al backside on Si, SiO₂ dielectric (around 127 nm thickness) and metallization consisting of 5 nm Ti (evap)\25 nm Ag (evap)\5 nm Al (evap) were prepared by photolithography and lift-off as described before.

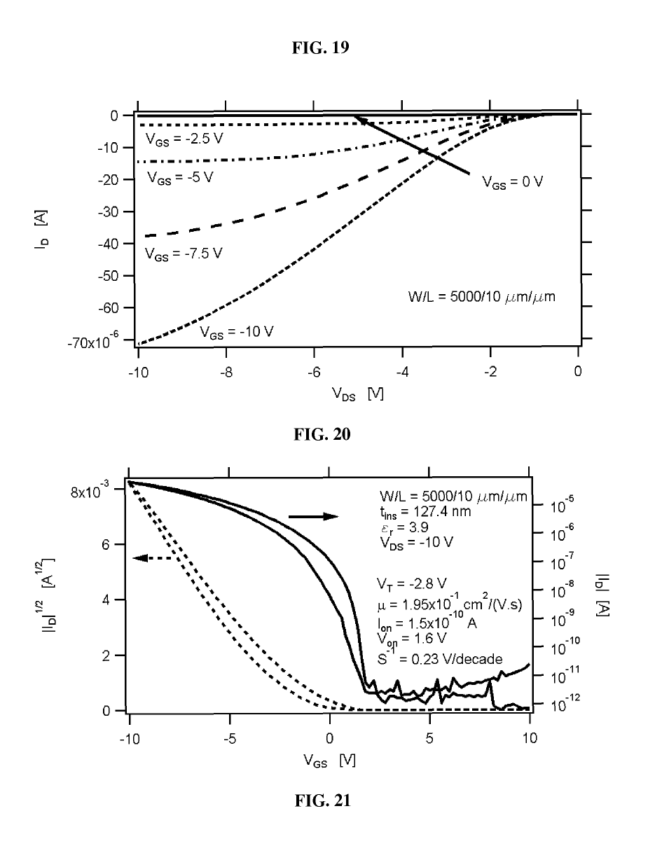

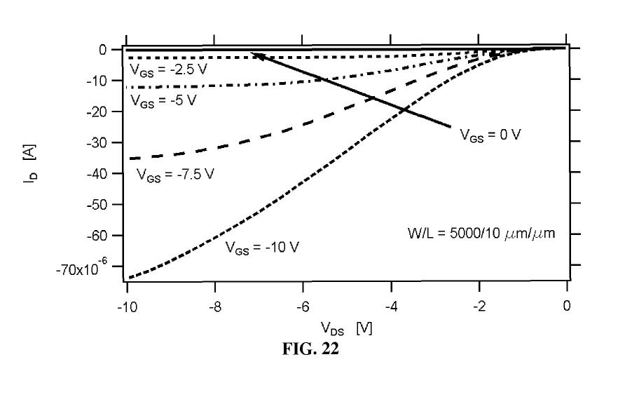

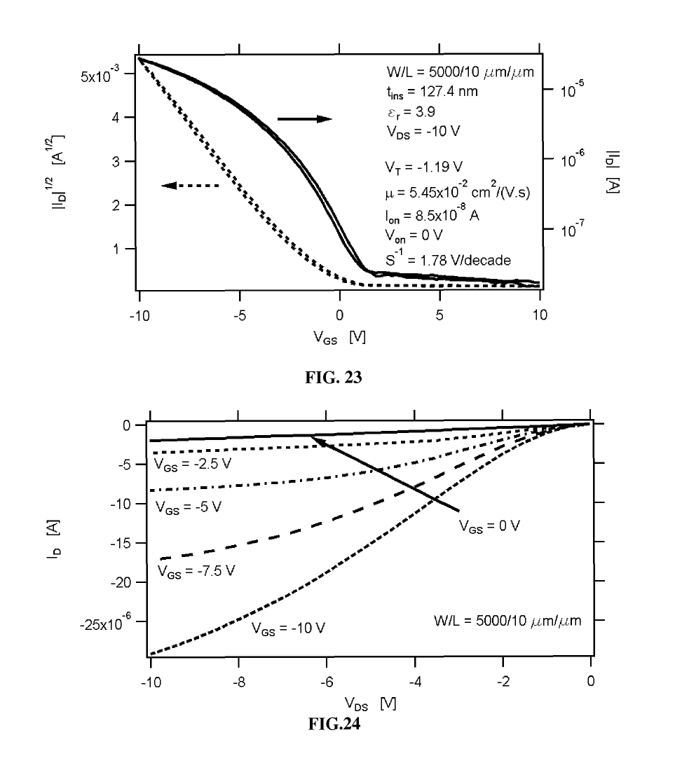

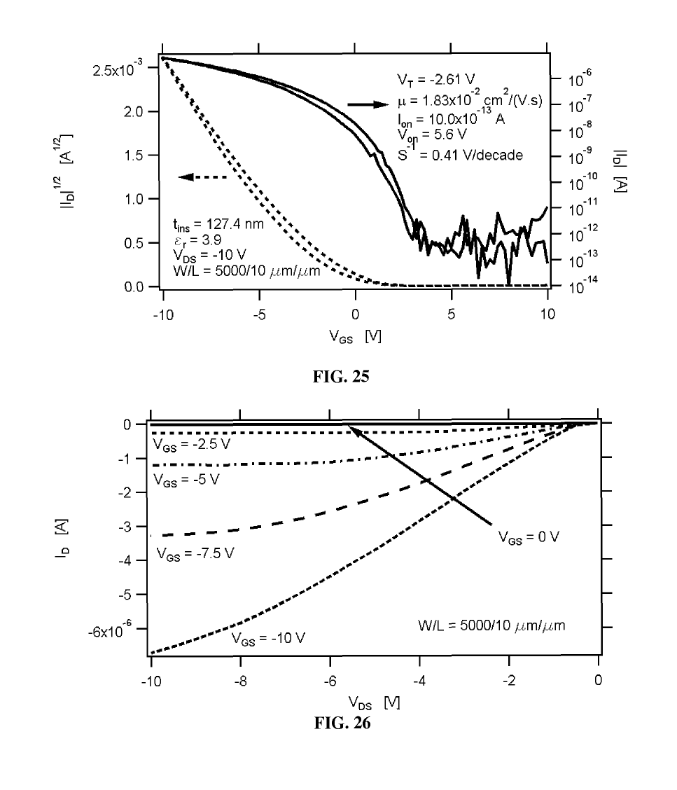

After cleaning with acetone, isopropylalcohol, followed by drying with nitrogen, a phenylethyltrichlorosilane (PETS) monolayer was deposited from gas phase. Then, the Al protection layer was removed by a solution consisting of 1 volume HCl mixed with 5 volumes of deionized water during 5 minutes. After rinsing with deionized water, acetone, isopropylalcohol and drying under a nitrogen flow, the samples were treated as follows:
One sample was placed for 10 minutes in a 5 millimolar solution of 1,2-benzenedithiol in absolute ethanol, rinsed afterwards with absolute ethanol, and dried under nitrogen flow (corresponding results of the final transistor are shown in FIGS. 19 and 20)
A second sample was placed for 10 minutes in a 5 millimolar solution of 1,2-benzenedimethanethiol in absolute ethanol, rinsed afterwards with absolute ethanol, and dried under nitrogen flow (corresponding results of the final transistor are shown in FIGS. 21 and 22)
A third sample was covered by spin-coating (6000 rpm, 60 sec) with poly(3,4-ethylenedioxythiophene)-poly(styrenesulfonate) (PEDOT:PSS, from H.C. Stark, Clevios P VP A1 4083); (corresponding results of the final transistor are shown in FIGS. 23 and 24)
A last sample was used without surface modification (corresponding results of the final transistor are shown in FIGS. 25 and 26)

Then, pentacene was deposited from vapor phase as described previously, and the obtained transistors measured in a nitrogen filled glovebox. Corresponding results shown in FIG. 19 to 24 show a relatively high saturation mobility for the short channel length (10 μm) of the used transistor substrates. Injections by the thiol modified silver contacts into pentacene was good, with saturation mobilities in the range of 0.1 to 0.2 cm²/(V·s) (FIGS. 19, 20, 21 and 22). Even transistors with PEDOT:PSS modified silver contacts (FIGS. 23 and 24) exhibited significant higher saturation mobilities (around 0.05 cm²/(V·s)) than the untreated silver contacts (0.02 cm2/(V·s), FIGS. 25 and 26)

It is to be understood that although preferred embodiments, specific constructions and configurations, as well as materials, have been discussed herein for devices according to the present invention, various changes or modifications in form and detail may be made without departing from the scope and spirit of this invention. For example, any formulas given above are merely representative of procedures that may be used. Functionality may be added or deleted from the block diagrams and operations may be interchanged among functional blocks. Steps may be added or deleted to methods described within the scope of the present invention.

1-83. (canceled)

84. A method for fabricating an organic device, comprising:
(i) providing a substrate having a surface comprising electrical contact structures and a dielectric portion;
(ii) providing a first temporary protection layer on at least some of the electrical contact structures;
(iii) providing at least one of a first surface modification layer on the dielectric portion and a third surface modification layer on the electrical contact structures not protected in step (ii);
(iv) removing the first temporary protection layer;
(v) providing a second surface modification layer on the electrical contact structures that were protected in step (ii);
(vi) providing the first surface modification layer on the dielectric portion if it was not provided in step (iii); and
(vii) providing an organic semiconductor layer on top of at least part of the first surface modification layer, the second surface modification layer, and, if present, the third surface modification layer.

85. The method of claim 84, wherein step (i) comprises:
providing the substrate;
providing the dielectric portion on the substrate; and
providing the electrical contact structures on the dielectric portion.

86. The method of claim 84, wherein in step (ii) the first temporary protection layer is provided on all of the electrical contact structures, wherein step (iii) consists in providing the first surface modification layer on the dielectric portion, and wherein step (vii) consists in providing the organic semiconductor layer on top of the first surface modification layer and the second surface modification layer.

87. The method of claim 84, wherein in step (ii) the first temporary protection layer is provided on some of the electrical contact structures, wherein in step (iii) the first surface modification layer is provided on the dielectric portion and the third surface modification layer is provided on the electrical contact structures not protected in step (ii), and wherein in step (vii) the organic semiconductor layer is provided on top of the first, second, and third surface modification layers.

88. The method of claim 84, wherein in step (ii) the first temporary protection layer is provided on some of the electrical contact structures, wherein step (iii) consists in providing the third surface modification layer on the electrical contact structures not protected in step (ii), wherein step (vi) consists in providing the first surface modification layer on the dielectric portion, and wherein in step (vii) the organic semiconductor layer is provided on top of the first, second, and third surface modification layers.

89. The method of claim 84, wherein in step (ii) the first temporary protection layer is provided on some of the electrical contact structures and wherein a further step is performed between step (ii) and step (iii) such that a second temporary protection layer is provided at least on the electrical contact structures not provided with the first temporary protection layer.

90. The method of claim 84, wherein in step (ii) the first temporary protection layer is provided on all of the electrical contact structures and wherein a further step is performed between step (ii) and step (iii) such that a second temporary protection layer is provided on some of the electrical contact structures covered by the first temporary protection layer.

91. The method of claim 84, wherein the step of providing the electrical contact structures and the step of providing the first temporary protection layer comprises patterning the electrical contact structures and the first temporary protection layer in a single lift-off step before providing the first surface modification layer.

92. The method of claim 84, wherein the first temporary protection layer is provided after forming the electrical contact structures.

93. The method of claim 84, wherein the step of removing the first temporary protection layer is performed by a chemical treatment that does not deteriorate the first surface modification layer.

94. The method of claim 84, wherein the first surface modification layer is different from at least one of the second surface modification layer and the third surface modification layer.

95. The method of claim 84, wherein at least one of the second surface modification layer and the third surface modification layer comprises one of a thiol, an organic disulfide, a substituted thiourea, an isothiocyanate, a thiophene, an imidazole-2-thione, a selenol, an organic diselenide, a thioacetate, a nitrile, or an isonitrile.

96. The method of claim 84, wherein the second surface modification layer comprises a charge-transfer complex.

97. The method of claim 84, wherein at least one of the second surface modification layer and the third surface modification layer are self-assembled monolayers.

98. The method of claim 95, wherein the third surface modification layer is a self-assembled monolayer selected so that a first bond strength with the electrical contact structure is lower than a second bond strength of the second surface modification layer with the electrical contact structure.

99. The method of claim 84, wherein the electrical contact structures are made of a metal and wherein the method further comprises reacting the electrical contact structures with one of an electron acceptor and a chemical compound or mixture of compounds acting as a dopant for a semiconductor at the electrical contact structures—semiconductor layer interface or improving charge injection into the semiconductor at the electrical contact structures—semiconductor layer interface.

100. The method of claim 84, wherein the organic device is selected from the group consisting of organic bottom contact transistors, transistor-diodes, Ion Sensitive Field Effect Transistors, Organic Light Emitting Diodes, organic diodes, and organic CMOS circuits.

101. The method of claim 84, wherein the organic device is an organic CMOS circuit and wherein step (v) comprises providing a first type of the second surface modification layer on a some of the electrical contact structures and providing a second type of the second surface modification layer on the electrical contact structures that are not provided with the first type of the second surface modification layer.

102. The method of claim 84, wherein the organic device is an organic bottom contact transistor and wherein step (i) comprises providing the substrate having at least one gate electrode, providing the dielectric portion on the substrate and on the at least one gate electrode, providing the electrical contact structures on the dielectric portion, wherein the dielectric portion is a gate dielectric layer, wherein the electrical contact structures are source and drain electrodes, wherein step (ii) comprises providing the first temporary protection layer on free surfaces of at least one of the source and drain electrodes, wherein step (iv) comprises removing the first temporary protection layer without removing the first surface modification layer from the gate dielectric layer, and wherein the step (v) comprises providing the second surface modification layer on the free surfaces of the source and drain electrodes.

103. An organic device, comprising:
a substrate;
a gate electrode and a gate dielectric layer on the substrate;
source and drain electrodes located on a portion of the gate dielectric layer;
a first surface modification layer covering the gate dielectric layer where the source and drain electrodes are not located;
a second surface modification layer covering surfaces of the source and the drain electrodes not in contact with the gate dielectric layer; and
an organic semiconductor layer on the first surface modification layer and the second modification layer.
